(19) United States
(12) Patent Application Publication
(10) Pub. No.: US 2025/0306463 A1
(43) Pub. Date: Oct. 2, 2025

(54) PATTERNING A SUBSTRATE USING A MULTI-PATTERNING TECHNIQUE

(71) Applicant: Tokyo Electron Limited, Tokyo (JP)

(72) Inventors: Steven Grzeskowiak, Albany, NY (US); Jodi Grzeskowiak, Schenectady, NY (US); David Conklin, Saratoga Springs, NY (US); Michael Murphy, Niskayuna, NY (US); David Power, Albany, NY (US); Anton deVilliers, Albany, NY (US); Eric Chih-Fang Liu, Albany, NY (US); Katie Lutker-Lee, Albany, NY (US)

(21) Appl. No.: 18/617,026

(22) Filed: Mar. 26, 2024

(51) Int. Cl. G03F 7/09; G03F 7/00; G03F 7/40; H01L 21/033; H01L 21/311

(52) U.S. Cl. CPC G03F 7/094; G03F 7/0002; G03F 7/40; H01L 21/0337; H01L 21/31144

(57) ABSTRACT

A method for patterning a substrate, the method includes forming a first mask over the substrate, the first mask including first features and first spaces and exposing the substrate at a bottom of each first space; forming a second mask while retaining the first features, the second mask including second features and second spaces, the second features covering a portion of the substrate exposed by the first spaces; and either selectively depositing on or selectively removing material from the second features relative to the first features to change a width of each of the second features.

### TECHNICAL FIELD

The present invention relates generally to methods for patterning a substrate, and, in particular embodiments, to a method for patterning a substrate using a multi-patterning technique.

### BACKGROUND

An integrated circuit (IC) is a network of electronic components in a monolithic structure comprising a stack of layers fabricated by processing a substrate through a sequence of patterning levels where, at each level, a layer of the substrate is formed and patterned. The patterning process uses photolithography to fabricate an etch mask over the substrate. In photolithography, a coating of resist is exposed to a pattern of actinic radiation and developed to print a patterned resist layer. The etch mask may be such a patterned resist layer formed over the substrate. The substrate is etched through spaces in an etch pattern of the etch mask to transfer the pattern to the substrate. However, with a scaling trend toward thinner resists, etch resistance of the resist layer may be inadequate, and a hardmask may be used as the etch mask for etching the substrate, where the hardmask is patterned using photolithography. At each new technology node, the minimum feature sizes in the patterned substrate are shrunk to reduce cost by increasing packing density. A higher resolution pattern may be printed by switching to a shorter wavelength light source. For example, the 248 nm KrF laser, introduced at the 250 nm node was replaced by the 193 nm ArF laser at the 90 nm node. The life of 193 nm optics has been extended to include even the 10 nm node by using resolution enhancement methods such as multi-patterning and immersion lithography. Recent introduction of 13.5 nm Sn-plasma source extreme ultraviolet (EUV) optics at the sub-10 nm nodes, along with a new class of resists, called metal based resists (MBR), provides new opportunities for innovation in patterning technology.

### SUMMARY

A method for patterning a substrate, the method includes forming a first mask over the substrate, the first mask including first features and first spaces and exposing the substrate at a bottom of each first space; forming a second mask while retaining the first features, the second mask including second features and second spaces, the second features covering a portion of the substrate exposed by the first spaces; and either selectively depositing on or selectively removing material from the second features relative to the first features to change a width of each of the second features.

A method for patterning a substrate, the method includes forming a first mask over the substrate, the first mask including first features and first spaces, the first mask exposing the substrate at a bottom of each first space; forming a second mask while retaining the first features, the second mask including second features and second spaces, the second features covering a portion of the substrate exposed by the first spaces; and either selectively depositing on or selectively removing material from the first features relative to the second features to change a width of a portion of each of the first features exposed after forming the second mask.

A method for patterning a substrate, the method includes forming a first mask over the substrate, the first mask including first features and first spaces, the first mask exposing the substrate at a bottom of each first space; forming a second mask over the first features, the second mask including second features covering a portion of the substrate exposed by the first spaces; forming a third mask while retaining the first features and the second features, the third mask including third spaces and exposing portions of the first features and portions of the second features; and selectively changing either widths of the exposed portions of the first features or the second features relative to the third mask.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a flowchart of a method for patterning a substrate, in accordance with some embodiments of the invention;

FIGS. 2A-2E illustrate various planar views of a substrate at intermediate stages of patterning using the method described in the flowchart in FIG. 1;

FIG. 3 illustrates a flowchart of a method for patterning a substrate, in accordance with some embodiments of the invention;

FIGS. 4A-4E illustrate various planar views of a substrate at intermediate stages of patterning using the method described in the flowchart in FIG. 3;

FIGS. 5A-5D illustrate various planar views of a substrate at intermediate stages of patterning using the method described in the flowchart in FIG. 6 in accordance with some embodiments of the invention;

FIG. 5E illustrates a planar view of a substrate at an intermediate stage of patterning using the method described in the flowchart in FIG. 6 in accordance with some embodiment of the invention; and

FIG. 6 illustrates a flowchart of a method for patterning a substrate, in accordance with some embodiments of the invention.

### DETAILED DESCRIPTION OF ILLUSTRATIVE EMBODIMENTS

The disclosure relates to a method for patterning a substrate using a multi-patterning technique. In embodiments of the method, an etch mask is formed from multiple masks stacked over the substrate, where each mask of the multiple masks has its respective pattern of lines and spaces. A width of each line is referred to as its critical dimension (CD). In the description of the embodiments, we have referred to a feature of the masking material as a line having a width, and a gap created by removing the masking material (e.g., an area between adjacent features) as a space. However, in various embodiments, features having various geometrical shapes may be patterned. For example, consider a pattern comprising an array of contact holes. The masking material between two adjacent contact holes may be considered to be a feature having a width equal to a dimension of the masking material along a line passing through a center of each of the two contact holes. As such the embodiments apply to any feature that can be patterned.

As described in further detail below, materials and processes used in forming the multiple masks are selected such that widths of the exposed portions of lines of each mask of the multiple masks may be adjusted independently by performing area selective processes. For example, if a material property of each mask is different from that of all the other masks in the stack, then an area selective process that selectively changes the width of each exposed line segment of a specific mask by a CD bias, may be possible, even in the presence of all the other masks in the stack of multiple masks. The etch mask is formed by completing the area selective processing that changes the widths of lines to their final values. The etch mask is a combined mask that includes all the masks of the multiple masks and has a plurality of through openings exposing a portion of the substrate at a bottom of each through opening. Each through opening is located where there is a common (i.e., vertically overlapping) region shared by a set of spaces, which includes a space from each of the multiple masks. Clearly, each through opening of the combined mask is a vertical channel through which etchants entering the combined mask at the top of the through opening may access the portion of the substrate at the bottom of the through opening. After the etch mask is formed, a flux of an appropriate etchant may be directed to flow along each of these channels to etch material off the exposed substrate at the bottom of the through opening. Thus a pattern of the through openings of the combined mask is an etch pattern of the etch mask, that is, spaces of the etch pattern are the through openings of the etch mask through which various particles may interact with the substrate 200 during processing. By etching the substrate with this etch mask, the etch pattern may be transferred from the etch mask to a pattern of openings in the substrate.

In an embodiment, where two masks are formed sequentially over the substrate, a CD bias may be applied to either of the two masks independently. For example, widths of the lines of the mask formed last (i.e., the topmost mask) may be biased by one value. Alternatively, widths of the lines of the mask formed first (i.e., the lowermost mask) may be biased by another value.

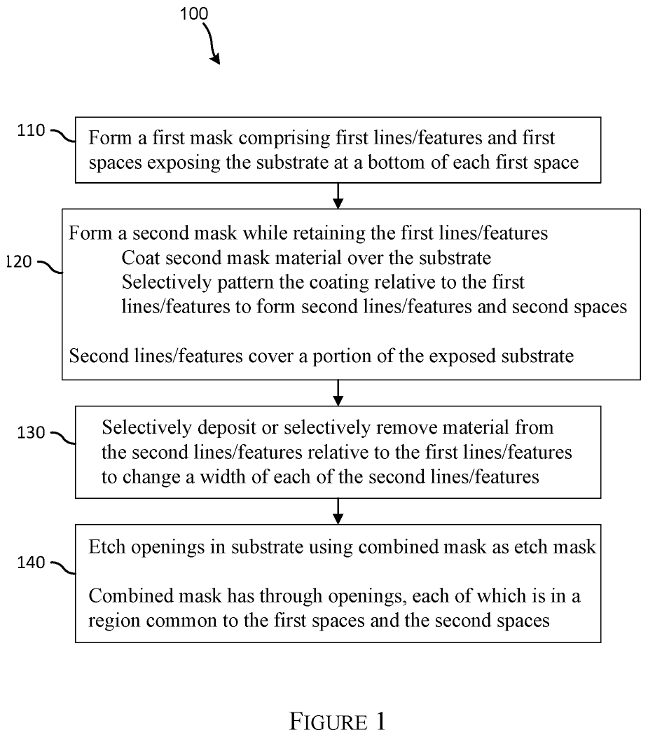

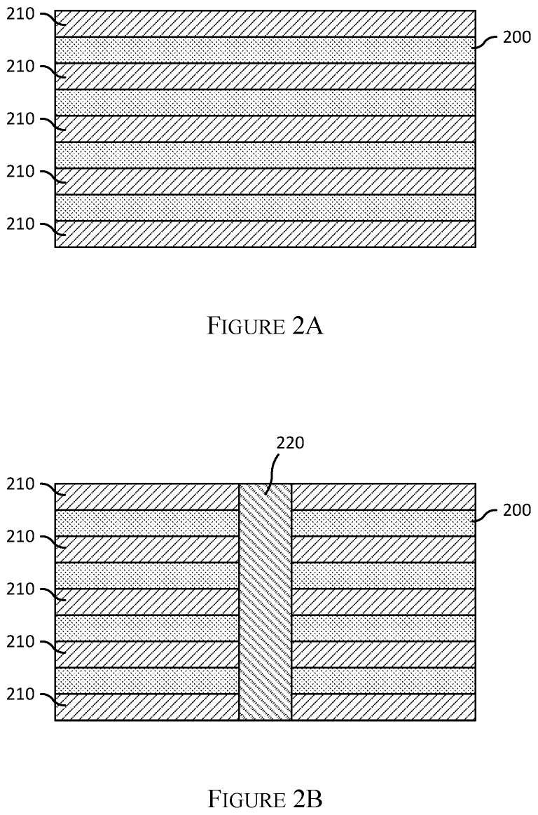

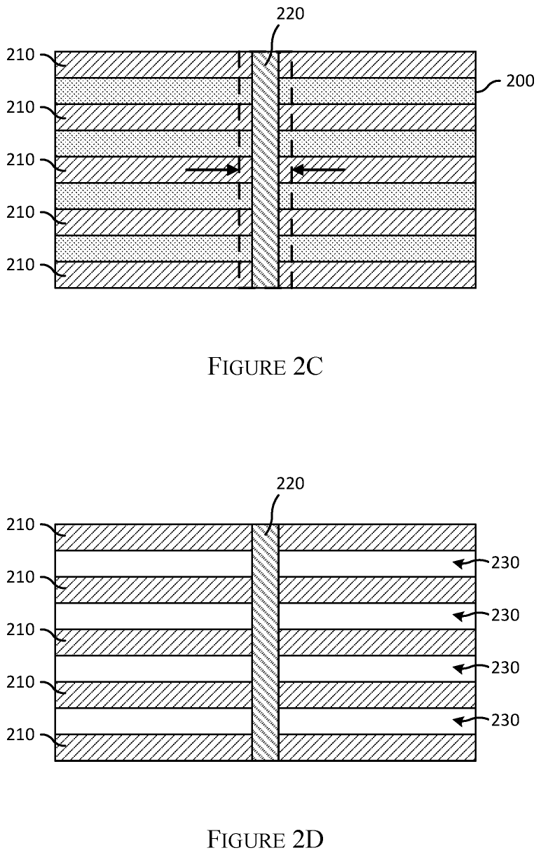

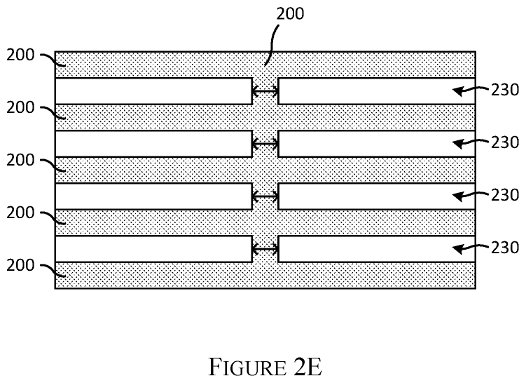

FIG. 1 shows a flowchart of a first patterning method 100 (described briefly above), where two masks are superimposed. FIGS. 2A-2E illustrate planar views of the structure as the substrate 200 is progressively processed through the first patterning method 100. As illustrated in box 110 of the flowchart and the planar view in FIG. 2A, a first mask 210, comprising first lines separated by first spaces, is formed over the substrate 200. An exposed portion of the substrate 200 is visible at the bottom of each first space. In the example embodiment illustrated in FIG. 2A, a pattern of first lines, indicated by hatched rectangles, is formed as parallel lines oriented in a first direction (the left-right direction in planar view in FIG. 2A).

In various embodiments, the first lines of the first mask 210 may comprise a first mask material. In some embodiments, the first mask material may be a resist. In some other embodiments, the first mask material may be a hardmask. In some embodiments, the first mask material may comprise more than one material. For example, the first lines may comprise more than one group of lines, where each group of lines comprises a unique material. The first mask 210 may be fabricated over the substrate 200 by various methods, each method using photolithography, as described in further detail below.

As illustrated in the planar view in FIG. 2B and in box 120 of the flowchart of the first patterning method 100, a second mask 220, comprising second lines and second spaces is superimposed over the first mask 210, thus forming a stack of two masks over the substrate 200. In the example embodiment illustrated in FIG. 2B, the second lines are also parallel lines, but formed in a second direction, different from the first direction. The second line of the second mask 220 (shown in the region illustrated in FIGS. 2A-2B) is orientated perpendicular to the first lines of the first mask 210. That is, the second direction and the first direction are perpendicular to each other. In some other embodiment, the first direction may be parallel to the second direction.

As indicated in box 120 in FIG. 1, the second mask 220 is formed while retaining the first lines of the first mask 210. A process for forming the second mask 220 comprises forming a coating of a second mask material over the substrate 200 and the first mask 210. A pattern of second lines separated by the second spaces may be etched in the coating by a patterning process. Similar to the first spaces, each second space is a through opening exposing a portion of the first mask 210. Since both the first spaces and the second spaces are through openings, the substrate 200 gets exposed through a vertically overlapping region common to the first spaces and the second spaces. The non-overlapping portion of the second spaces exposes a portion of the first lines of the first mask 210.

In some embodiments, the second mask material may be a resist. In some other embodiments, the second mask material may be a hardmask. In some embodiments, the second mask material may comprise more than one material. The coating of second mask material has to be selectively patterned to retain the first lines of the first mask 210 undamaged through the patterning process. In order to selectively pattern the second lines relative to the first lines, the second mask material may be selected to be different from the first mask material. In embodiments where the second mask material is similar to the first mask material, the patterning process for forming the second lines may expose the first lines to etchants that may damage the first lines. In such embodiments, selectively patterning the second lines relative to the first lines may be achieved by performing a freezing process prior to coating the substrate 200 and the first lines with the second mask material. The freezing process protects the first mask 210 from being damaged during the forming of the second mask 220. In some embodiments, the freezing process comprises treating the first mask 210 with a flux of ballistic electrons, i.e., electrons with enough momentum directed toward the substrate to enter the first lines of the first mask 210. Treating the first mask 210 with a flux of ballistic electrons induces cross-linkage to alter the first mask material to be more resistant to being affected by subsequent exposure to light and developer solutions and other etchants. In some embodiments, the freezing process comprises depositing a freezing agent. The freezing agent is used to form a protective layer over the first features. For example, in some embodiment, the freezing agent is silicon, deposited by a plasma process with a DC superposition (DCS) function. As described in further detail below, a plasma processing chamber having the DCS function may be configured to sputter deposit a material, for example, silicon by using one of the electrodes in the plasma processing chamber as a sputter target. The sputtered silicon may serve as the protective layer. In some embodiments, the sputtered silicon layer may be oxidized by exposure to air to form a protective layer of silicon oxide over the first mask 210. In some embodiments, the freezing process with the DCS function is also used to treat the first mask 210 with a flux of ballistic electrons, as described in further detail subsequently in this disclosure. In another example embodiment, the freezing agent is a resin and a cross-linker additive material, and, after depositing the freezing agent, a baking step is performed to thermally activate cross-linkage in the resin, which increases its resistance to etchants to form an effective protective layer over the first lines. Alternatively, in some embodiments, the first mask material may be a resist having a resin and a cross-linker additive material. After patterning the first lines, the resist may be frozen by performing a baking step where the bake thermally activates cross-linkage to alter the first mask material to be more resistant to being affected by subsequent exposure to light and developer solutions and other etchants.

The first mask 210 and the second mask 220 may be fabricated by various methods, each method using photolithography. Some example methods are described in further detail subsequently in this disclosure.

After forming the second mask 220, the width of each second line is selectively changed relative to the first lines, as indicated in box 130 of the flowchart in FIG. 1 and shown in the planar view illustrated in FIG. 2C. In other words, in the first patterning method 100, each first line retains its width while the second lines are formed and, after this initial pattern of second lines is formed, the width of each second line is adjusted by a CD bias. The CD bias applied to each second line is referred to as a second CD bias in this disclosure.

Biasing the second lines selectively with the second CD bias (i.e., while retaining the widths of the first lines) may be achieved by selecting different materials for the first mask material and the second mask material or by freezing the first mask 210. As described above, in some embodiments, the freezing process may be coating the first lines with the protective layer. In some embodiments, along with coating the first lines, the freezing process may be coating the exposed portion of the substrate 200 with the protective layer. In some embodiments, the freezing process may be altering the composition of each of the first lines by inducing cross-linkage in the entire line. Having first lines and second lines comprising different materials or having the first mask 210 frozen, enables selective processing for changing the widths of the second lines while retaining the widths of the first lines. For example, an area selective deposition process may be used to increase the width of the second lines. The area selective deposition process may be configured such that material is selectively deposited on the second lines relative to the exposed portions of the first lines and the substrate. Likewise, a selective etch process may be used to reduce the width of the second lines. The selective etch process may be an area selective etch, configured to remove material selectively from the second lines relative to the exposed portions of the first lines and the substrate.

As mentioned above, the first patterning method 100 retains the first lines of the first mask 210, including the width of each first line. The width of each first line is to be retained through the selective patterning process used to form the initial pattern of second lines and through the selective processing for changing the width of each second line. However, the selectivities achieved by various selective patterning processes is finite, hence the widths of the first lines may change by a finite amount due to the patterning process used to pattern the second mask material. The various freezing processes may also perturb the CD of the first lines. In some embodiments, the freezing process may increase the width of each of each first line by forming the protection layer. In some embodiments, where the first mask material includes a resin and a cross-linker additive material, the freezing process comprises inducing cross-linkage in the first lines, which may also increase the width of each first line.

In addition to the selective patterning processes, the selective processing for changing the width of each second line, i.e., the various selective deposition and selective etch processes used in applying the second CD bias, have limited selectivities. Thus, it is understood that the widths of the first lines may not be retained totally unchanged, but it is acceptable if the change is similar or smaller than a statistically random variation in the CD of the first lines.

As mentioned above, in some embodiments, the second mask material is selected to be different from the first mask material in order to selectively pattern the second lines relative to the first lines. In these embodiments, an area selective process may be performed that selectively changes the width of each second line (comprising the second mask material) relative to the first lines (comprising the first mask material) by the second CD bias. In some embodiments, the width of each second line is increased. The width increase may be achieved by performing an area selective deposition process configured to selectively deposit material on the second lines relative to the first lines and the substrate. In some embodiments, the width of each second line is reduced. The width reduction may be achieved by performing an area selective etch process configured to selectively remove material from the second lines relative to the first lines and the substrate. The area selective etch process may be a wet etch or a dry etch. In some embodiments, where one of the mask materials is an organic resist and the other is an inorganic material (e.g., a hardmask), a thermal chemical etch process may be used to increase the solubility of one of the mask materials in an organic solvent. In the thermal chemical etch process, an overcoat comprising a thermal acid generator (TAG) is formed. Then a bake is performed that diffuses the TAG into a peripheral region of the lines within a controlled distance from the edges. This region, having a higher solubility, may be removed to reduce the width of the lines by a controlled amount.

As mentioned above, in some embodiments, the etch resistance of organic resists to a solvent, for example, propylene glycol monomethyl ether (PGMEA) or tetramethylammonium hydroxide (TMAH) may be increased by the freezing process (i.e., cross-linkage), and the etch resistance to plasma (e.g., oxygen or fluorocarbon plasma) may be increased by selecting a resist comprising a high etch resistant polymer, as explained in further detail below. With the freezing process having altered the solubility, an area selective etch may be performed using the solvent.

In the first patterning method 100, after completing forming the second mask 220, the width of each second line is selectively changed relative to the first lines of the first mask 210 (see box 130 in FIG. 1). The top view in FIG. 2C illustrates that, in the example embodiment, the second CD bias has reduced the width of the second line relative to its previous width (indicated by dashed vertical lines and arrows in FIG. 2C). Note that the widths of the first lines of the first mask 210 have been retained.

In one embodiment, the first lines comprise, for example, a frozen (i.e., etch resistant) organic chemically amplified resist (CAR) used for 193 nm deep ultraviolet (DUV) radiation. Typically, a CAR for 193 nm DUV comprises an acrylic resin, photoacid generators (PAGs), quencher, and an organic casting solvent. A cross-linker additive material (e.g., tetra(methoxymethyl)glycoluril (TMMG) or diethyleneglycol diacrylate ((DEGDA)) A pattern of first lines may be formed by using suitable exposure and develop processes, for example, exposing the CAR to a radiation pattern and developing the pattern with a developer solution comprising, for example, TMAH. The formed pattern of first lines may be frozen by performing a high temperature freezing bake that thermally activates the cross-linker additive material in the organic CAR. Generally, the freezing bake is performed at a higher temperature relative to the pre-exposure and post-exposure photolithography bakes. As mentioned above, the cross-linkage alters the patterned CAR to be more resistant to being affected by subsequent exposure to light and developer solutions and other etchants, including TMAH. In other words, the CAR is converted to frozen CAR, thus completing the patterning process of forming the first mask 210. In various embodiments, a ratio of an etch rate of CAR to an etch rate of frozen CAR in TMAH may be from about 1.5 to about 20.

Adjusting the width of each of the second lines with the second CD bias completes forming both the first mask 210 and the second mask 220. Since the first patterning method 100 is a two mask multi-patterning method, the etch mask is the combined mask comprising a pattern of lines and spaces, where the lines include the first lines of the first mask 210 and the second lines of the second mask 220, as illustrated in the planar view in FIG. 2C. The spaces of the combined mask are through openings exposing a portion of the substrate 200. Each through opening is located where there is a common (i.e., vertically overlapping) region shared by a first space of the first mask 210 and a second space of the second mask 220. This pattern of spaces of the combined mask is the etch pattern of the etch mask.

In FIG. 2D and box 140 of the flowchart of the first patterning method 100, a pattern of openings 230 is etched using the combined mask (described above with reference to FIG. 2C) as the etch mask. Forming the pattern of openings 230 transfers the etch pattern of the etch mask to the substrate 200.

After completing the pattern transfer, the second mask 220 and the first mask 210 may be removed using, for example, an oxygen plasma ashing step. FIG. 2E illustrates a planar view of the transferred pattern revealed after removing the second mask 220 and the first mask 210.

Note that, in the example embodiment described with reference to FIGS. 2A-2E, the second CD bias is a width reduction of each second line, which resulted in reducing a tip-to-tip distance between two laterally adjacent openings in the pattern of openings 230 etched using the first method of patterning 100, as indicated by double arrows in Figure-2E. In some other embodiment, the second CD bias may be a width increase of each second line using an area selective deposition process. The selectivity for the area selective deposition process may be provided by selecting different materials for the first lines and the second lines. Even if the first mask material and the second mask material comprise organic resists, it may be possible to provide selectivity by freezing the first lines. For example, if the first mask 210 comprises a resist that has been frozen by the freezing process with the DCS function (mentioned above) then there would be a protective layer comprising, for example, silicon oxide, formed over the first lines of the first mask 210. This protective layer may provide selectivity between the first lines and the second lines to perform an area selective deposition.

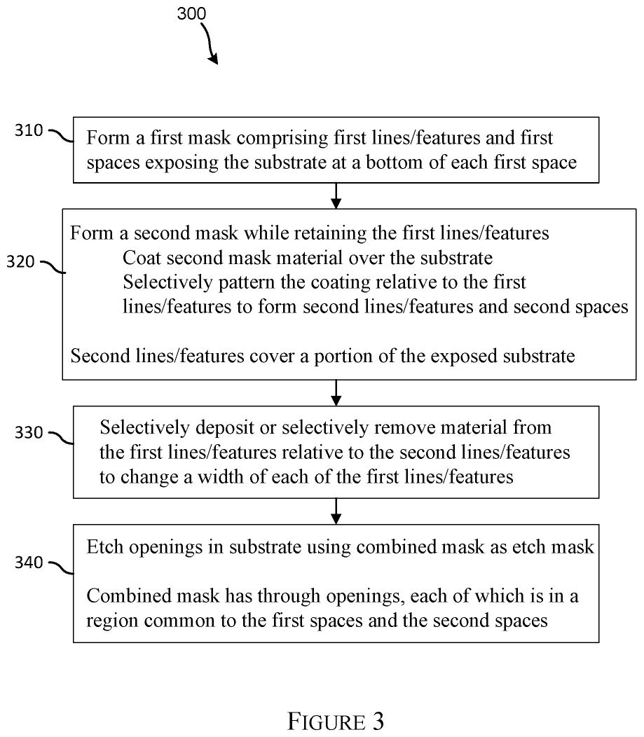

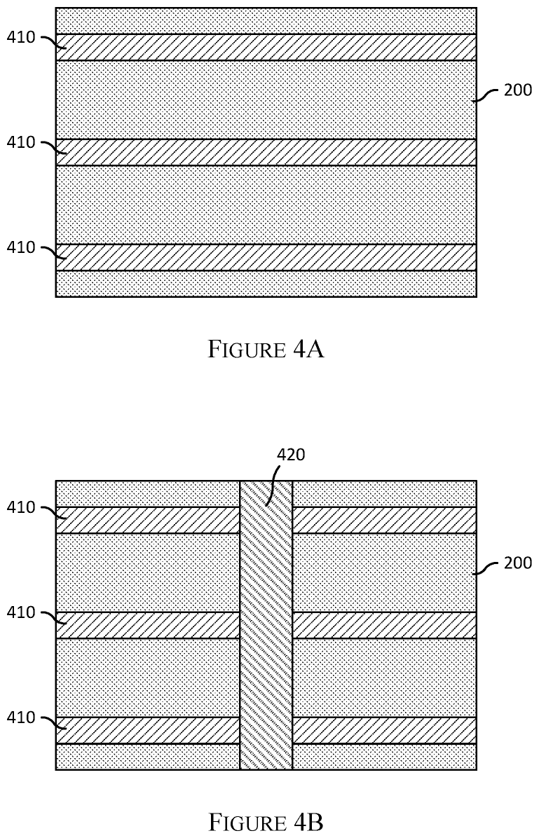

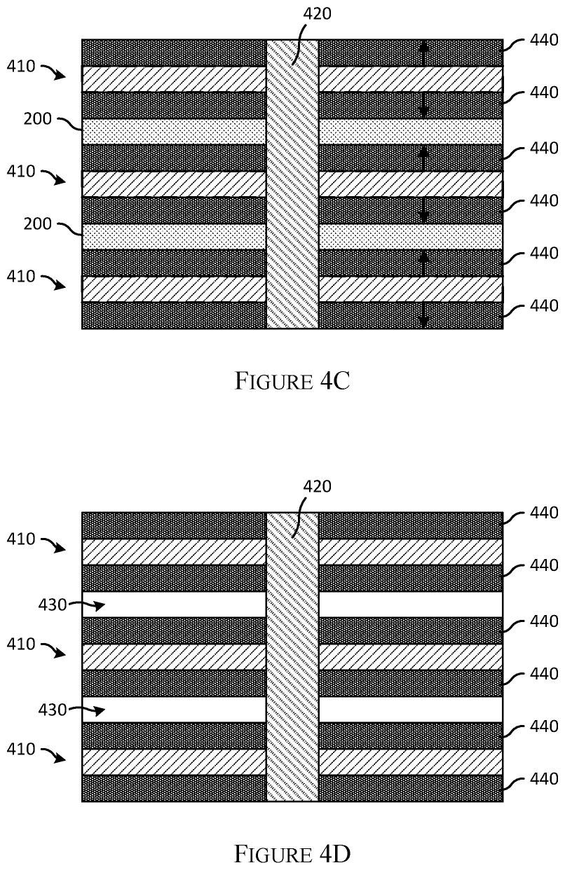

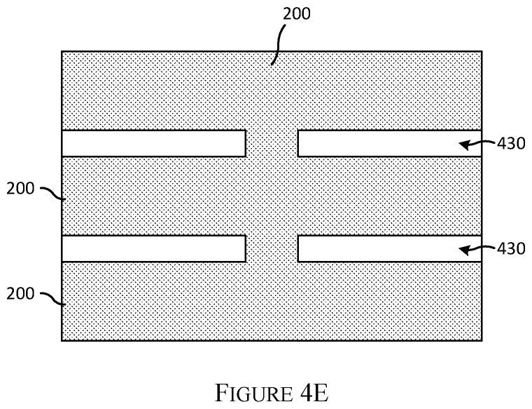

FIG. 3 shows a flowchart of a second patterning method 300, similar to the first patterning method 100 except, in the second patterning method 300, the width of each of the first lines is changed by a first CD bias instead of changing the width of each second line by a second CD bias. FIGS. 4A-4E illustrate planar views of the structure as the substrate 200 is progressively processed through the second patterning method 300.

As indicated in box 310 and box 320 in the flowchart of the second patterning method 300 and illustrated in the planar views in FIGS. 4A-4B, two masks are fabricated sequentially over the substrate 200. After forming a first mask 410, comprising first lines and first spaces (as illustrated in FIG. 4A), a second mask 420 is formed superimposed over the first mask 410, similar to the first patterning method 100. However, in this example embodiment, the first mask material is a metal based resist (MBR), typically used in 13.5 nm extreme ultraviolet (EUV) photolithography, which is being introduced in manufacturing ICs at the sub-10 nm nodes. The MBR resists incorporate metal atoms having a high capture cross-section for EUV photons in order to increase the EUV photon absorption relative to traditional organic CAR. An increasingly high aspect ratio of resist features with lateral scaling makes organic resists prone to resist bowing and collapse since the materials are generally too weak to be mechanically stable at high aspect ratios. This has led to the development of MBR, a new class of hybrid organic-inorganic resists, where the inorganic unit of the MBR includes metal atoms selected to enhance absorption of EUV photons, increase etch resistance, and provide higher mechanical strength.

In some embodiments, the MBR used as the first mask material for the first mask 410 comprises a metal-oxide resist (MOR) comprising Sn-oxo cluster. In various embodiments, the MBR for the first mask 410 may comprise oxides of Zr, Hf, Ti, Zn, or In. In some other embodiments, an inorganic resist such as hydrogen silsesquioxane (HSQ) may be used as the first mask material.

The first mask material may be patterned using a suitable photolithography process such as 13.5 nm EUV photolithography to form an initial pattern of first lines.

The second mask material for the example embodiment of the second method of patterning 300 may be an organic CAR. The organic CAR may be coated over the substrate 200 and the patterned MBR or patterned inorganic resist (e.g., HSQ) of the first lines, and the coating patterned using, for example, 193 nm DUV photolithography to form the second mask 420 using materials and processes similar to those described above for the first method of patterning 100. The photolithography processes for patterning the first mask material may be selected such that patterning the second mask material does not damage the patterned first lines. For example, in one embodiment, the first mask material is a negative tone MBR. Since the MBR being used is a negative-tone resist, the first lines comprise exposed resist. Having been already exposed, there is negligible effect on the first lines due to exposure to 193 nm DUV during the patterning of the second lines. As illustrated in FIG. 4B, the pattern of second lines is superimposed over the initial pattern of first lines.

Next, as indicated in box 330 of the flowchart of the second method of patterning 300, the width of each of the first lines of the first mask 410 are changed by the first CD bias while the width of each of the second lines of the second mask 420 is retained. In this example embodiment, the first CD bias increases the width of each first line, as illustrated in the planar view in FIG. 4C. The top view in FIG. 4C illustrates that, in the example embodiment, the first CD bias has increased the width of each first line relative to its previous width (indicated by dashed horizontal lines and arrows in FIG. 4C). Note that the widths of the second lines of the second mask 210 have been retained. A deposited material 440, deposited along the first lines of the first mask 410 has been formed using an area selective deposition process. For area selective deposition, a plasma process using process gases such as CO, CH₄, or silicon-based precursors (e.g., SiCl₄) can used to deposit materials selectively onto one material relative to another. For example, organic material can be deposited selectively onto an organic CAR when using gases such as CO or CH₄. This process can be selective to certain inorganic materials such as silicon, silicon oxide, a silicon-based resist such as HSQ, or metal-based resists. Similarly, an inorganic material may be deposited selectively onto an organic CAR when using a silicon-based precursor. The deposited material 440 increases the width of each first line of the first mask 410 (as indicated by arrows), thus covering a fraction of the previously exposed portion of the substrate 200, as illustrated in FIG. 4C.

Note that in FIGS. 4C and 4D, the first lines as initially patterned are indicated with dashed lines and shaded same as in FIG. 4A for the sake of clarity of understanding. It is understood that, in various embodiments, the tops of the first lines may also be covered by the selectively deposited material 440.

Adjusting the width of each of the first lines with the first CD bias completes forming both the first mask 410 and the second mask 420. Similar to the first method of patterning 100, in the second method of patterning 300, the etch mask is the combined mask comprising a pattern of lines and spaces, where the lines include the first lines of the first mask 410 and the second lines of the second mask 420 and the spaces of the combined mask are through openings exposing a portion of the substrate 200. As before, each through opening is a vertically overlapping region common to a first space and a second space. This pattern of spaces of the combined mask is the etch pattern of the etch mask.

In FIG. 4D and box 340 of the flowchart of the first patterning method 100, a pattern of openings 430 is etched using the combined mask as the etch mask. Forming the pattern of openings 430 transfers the etch pattern of the etch mask to the substrate 200.

After completing the pattern transfer, the second mask 420 (comprising organic CAR) may be removed using, for example, an oxygen plasma ashing step and the first mask 410 (comprising Sn-oxo cluster MBR and the deposited layer 440) may be removed using halogen based plasma step. FIG. 4E illustrates a planar view of the transferred pattern of openings in the substrate 200 revealed after removing the second mask 420 and the first mask 410.

As illustrated in FIGS. 4A-4E, increasing the width of each first line by the first CD bias has resulted in narrowing the openings 430 etched in the substrate 200. In some other embodiment, the first CD bias may be a width reduction of each first line using a selective etch process, for example, a halogen based plasma etch process.

As described above, the first method of patterning 100 and the second method of patterning 300 use two masks stacked over the substrate 200. A third method of patterning 500 adds a third mask comprising a pattern of third spaces over the first mask and the second mask. The purpose of the third mask is to select a window defined by the third spaces in which to apply either a first CD bias on each of the segments of first lines within the window or a second CD bias on each of the segments of first lines within the window.

As in the methods where two masks are stacked, the masks have to be formed by selective patterning. Likewise the CD bias (either the first CD bias or the second CD bias) has to be applied selectively to the first lines or the second lines, as specified by a process recipe. If applied to the first lines then the selective processing has to be selective to the second mask and the third mask, and if applied to the second lines then the selective processing has to be selective to the first mask and the third mask. The selective patterning and applying the CD bias in the third method of patterning 500 may be using materials and processes similar to those described above for the first method of patterning 100 and the second method of patterning 300.

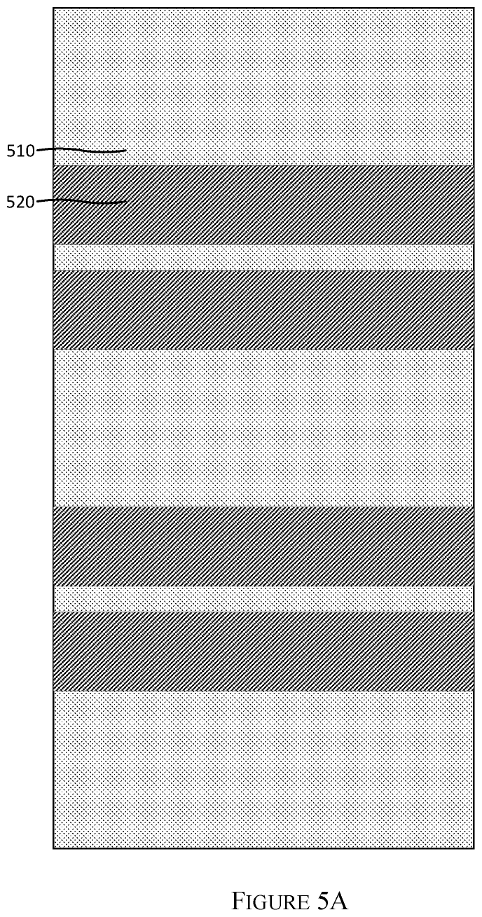

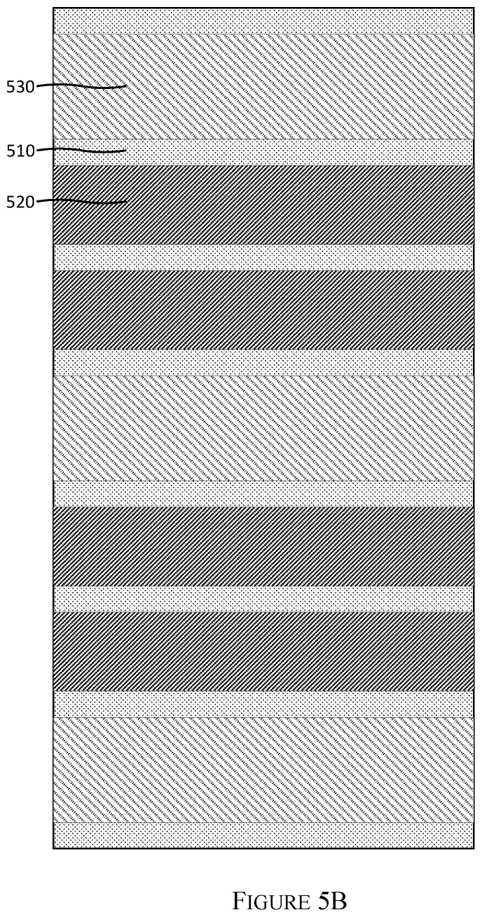

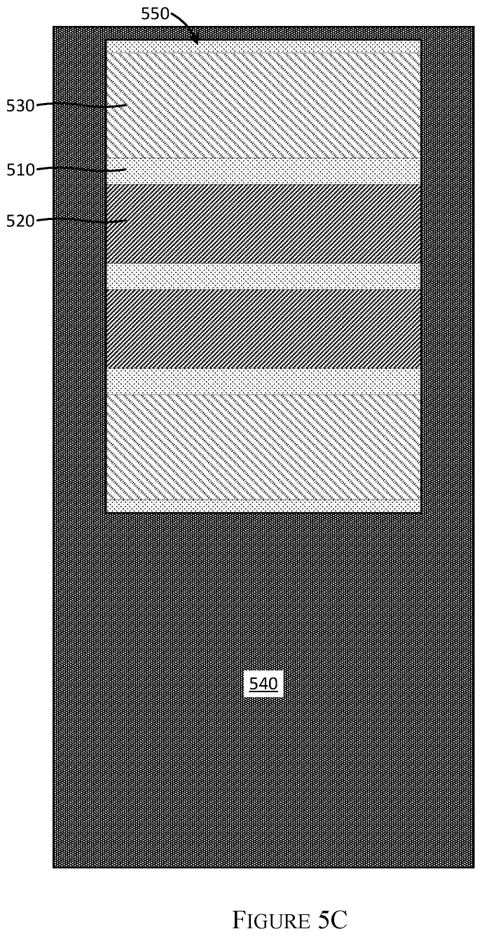

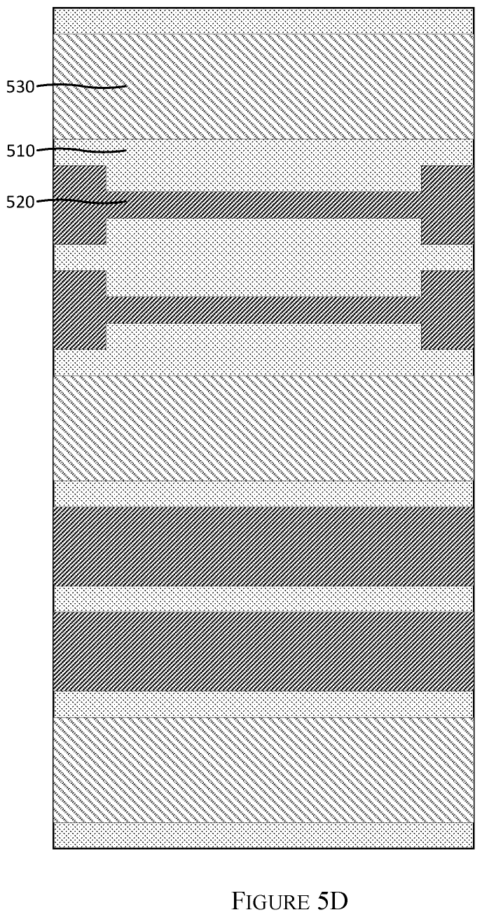

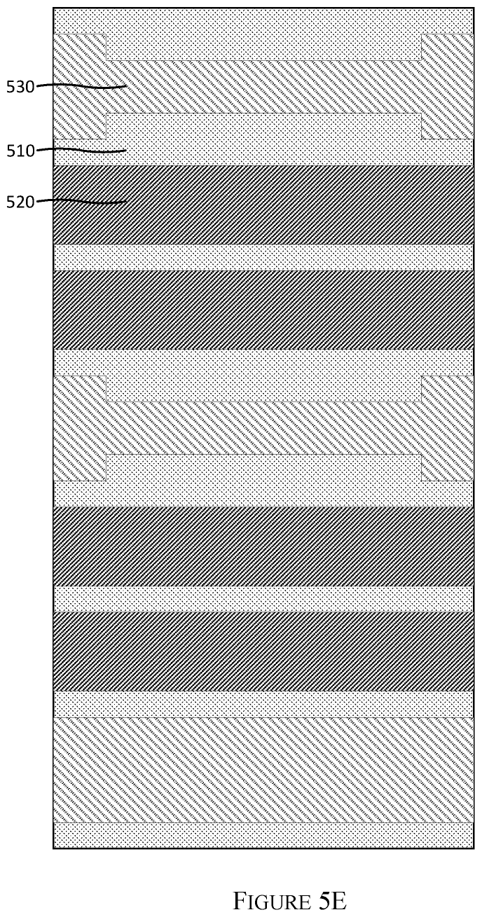

The third method of patterning 500 is described with reference to planar views of a structure, as illustrated in FIGS. 5A5C.

FIG. 5A illustrates a planar view of a substrate 510 over which a first mask 520, comprising first lines and first spaces, is formed. The first mask 520 exposes a portion of the substrate 510. The first lines may be comprising a first mask material.

In FIG. 5B, a second mask 530, comprising second lines and second spaces has been formed over the substrate, while retaining the first lines of the first mask 520 by selectively patterning the second mask 530. In the example in FIG. 5B, the first lines and the second lines are non-intersecting parallel lines oriented parallel to each other. In some embodiments, the second lines may comprise a second mask material different from the first mask material.

In FIG. 5C, a third mask 540 is formed over the substrate 510, superimposed on the first mask 520 and the second mask 530. The third mask is formed by selectively patterning a third mask material in order to retain the first lines and the second lines. In some embodiments, at least one of the mask materials is different from the other two mask materials. Of the two masks which comprise similar materials, the mask formed earlier may be frozen to provide the etch selectivity needed to perform a subsequent width reduction etch. In some embodiments, the third mask material may be different from the first mask material and the second mask material. In some embodiments, all three mask materials may be different. The combined spaces of the third mask define a window exposing two sets of line segments. As illustrated in FIG. 5C, a space of the third mask has defined a window 550. Within the window 550, in a first set of line segments, each line segment is a segment of a first line of the first mask 520, and in a second set of line segments, each line segment is a segment of a second line of the second mask 530.

After forming the third mask, either a first CD bias is selectively applied to each line segment of the first set of line segments or a second CD bias is selectively applied to each line segment of the second set of line segments. In this example, the first CD bias reduces a width of each of the first line segments using a selective etch process. Likewise, the second CD bias reduces a width of each of the second line segments using some other selective etch process. After the selective etching is complete, the third mask 540 is selectively removed by a suitable wet etch or dry etch.

FIG. 5D illustrates the first mask 520 and the second mask 530 after the third mask is removed for the embodiment, where the first CD bias has been applied to the first set of line segments within the window 550. The combined mask comprising the first mask 520 and the second mask 530 (after removing the third mask) is the etch mask. As illustrated in FIG. 5D, the exposed first line segments have a reduced width.

FIG. 5E illustrates the first mask 520 and the second mask 530 after the third mask is removed for the embodiment, where the second CD bias has been applied to the second set of line segments within the window 550. Again, the combined mask comprising the first mask 520 and the second mask 530 (after removing the third mask) is the etch mask. As illustrated in FIG. 5E, in this embodiment, the exposed second line segments have a reduced width.

Note that, both the etch mask illustrated in FIG. 5D and FIG. 5E, comprise a pattern of through openings which is the etch pattern of the etch mask exposing a portion of the substrate 510. In a subsequent etch process step, the etch mask may be used to transfer the etch pattern to a pattern of openings in the substrate 510.

As mentioned above, in some embodiments of the methods of patterning described in this disclosure, the freezing process comprises depositing a protective layer by a plasma process with a DCS function. An example of such a process is described herein.

The freezing process using the DCS function comprises depositing a protective layer comprising, for example, silicon over the substrate by performing a plasma process in a capacitively coupled plasma (CCP) chamber configured to perform a DC superposition (DCS) function. The plasma chamber is configured to have a top electrode disposed above the substrate, the substrate being held over a bottom electrode opposite the top electrode. One side of the top electrode, which faces the bottom electrode comprises a silicon target. The plasma processing with the DCS function comprises exposing the substrate and the first mask to plasma sustained in a region of the plasma chamber between the silicon target of the top electrode and the substrate held over the bottom electrode while biasing the top electrode negative relative to the bottom electrode. Biasing the top electrode comprises applying a DC bias by coupling a DC power supply to the top electrode. The plasma may be generated by ionizing a gas flowing through the plasma chamber using radio frequency (RF) source power superposed on the DC bias. The RF source power may be supplied by an RF power supply coupled to the top electrode or the bottom electrode and the gas may comprise, for example, argon to generate positively charged argon ions (Ar⁺). The Art ions in the plasma, being attracted by the negative polarity of the applied DC bias of the top electrode, get accelerated through an electric field in a plasma sheath region proximate the top electrode to strike the silicon target with sufficiently high momentum to sputter silicon atoms off the silicon target. Some of the sputtered silicon may deposit on the first lines and the substrate exposed in the first spaces to form a protective layer over the first mask 210. In some embodiments, the sputtered silicon layer may be oxidized by exposure to air to form a protective layer of silicon oxide over the first mask 210.

In addition to sputtering silicon, the incident Ar⁺ particles generate secondary electrons that are repelled away from the negatively biased top electrode and move toward the bottom electrode in a wide flux of ballistic electrons. The ballistic electrons may penetrate the plasma and emerge at the bottom to enter the first lines comprising the first mask material. As known to persons skilled in the art, treating a layer of resist with such a ballistic flux of electrons may induce cross-linking, which alters the resist material to be resistant to subsequent exposure to light and developer solutions. Thus, in embodiments where the first mask material comprises a resist, performing the plasma process with the DCS function freezes the pattern of first lines not only by forming the protective layer but also by altering the first mask material to be more resistant to damage since, during the plasma processing the first mask material is modified to be a resist treated by this flux of electrons.

Several patterning methods for forming a mask has been described above in the context of forming the first mask or the second mask in various embodiments. The methods have patterned lines comprising resist using single patterning. In some embodiments, the first lines may comprise a first resist different from the second mask material used to form the second lines. In some embodiments the first resist undergoes a freezing process prior to coating the substrate with the second mask material. However, as known to persons skilled in the art, many other methods are available. A few more examples of forming masks are described below.

In some embodiments, the first lines comprise a hardmask, where the hardmask is patterned using a patterned resist mask. The hardmask may be different from the second mask material. Examples of materials that may be used as a hardmask include silicon based materials such as amorphous silicon, polycrystalline silicon, silicon oxide, silicon nitride, silicon oxynitride and silicon carbide. In some embodiments, the hardmask may comprise an organic bottom antireflective coating (BARC) or an inorganic BARC such as a silicon-based antireflective coating (SiARC). In some embodiments, the hardmask may comprise metals or metal compounds such as Ti, W, TiN, Al₂O₃, TiSi₂, etc. In some embodiments, the hardmask may comprise organic material such as amorphous carbon layer (ACL) and spin-on hardmask (SOH).

In some embodiments, the first mask may be a hardmask patterned using a double-patterning technique such as a litho-etch-litho-etch (LELE) process, a litho-freeze-litho-etch (LFLE) process, or a self-aligned sidewall image transfer (SIT) process. The SIT process patterns a hardmask using a single resist pattern to pattern mandrels, forms sidewalls on opposite sides of the mandrels, and selectively removes the mandrels leaving the sidewalls as the etch mask to transfer the pattern of sidewalls to the hardmask layer.

In some embodiments, forming the first mask comprises forming the first lines by performing an antispacer patterning process. In this method the first lines comprise two types of lines, viz., mandrel lines and filler lines. First mandrel lines are patterned over the substrate using photolithography. The mandrels may comprise an organic material. The spaces between the mandrel lines are overfilled with an overcoat material. The filler material may also be an organic material. Either the mandrel material or the overcoat material comprises a chemically active species that may chemically alter the other material to a highly soluble anti-spacer material. The chemically active species may be a TAG, which is activated thermally to alter the solubility of specific organic materials in a solvent (e.g., TMAH). After forming the overcoat, a bake is performed to diffuse the chemically active species a controlled distance across a periphery between the mandrel lines and the overcoat material. The thermally activated chemically active species converts a region within a diffusion distance across the periphery to the anti-spacer material. The converted region would be formed self-aligned to the periphery, thus separating the mandrels from the overcoat filler material. A recess etch is performed that recesses the overcoat material to below the top surface of the anti-spacer material, thus forming filler lines on opposite sides of the mandrel lines, with the anti-spacer material being a separator between each mandrel line and adjacent filler line. The anti-spacer material now has an exposed top surface. Since the anti-spacer material is highly soluble in a solvent, the solvent may selectively remove the anti-spacer material relative to the mandrel material and the overcoat material. The spaces vacated by the selective removal of anti-spacer material exposes the substrate at the bottom each space. Thus, the pattern of alternating mandrel and filler lines may serve as the first mask over the substrate.

In some embodiments, after removing the anti-spacer material, a freezing process with the DCS function may be performed prior to forming the coating of second mask material. As described in detail above, the freezing process with the DCS function forms a protective coating over the first mask. In this embodiment, the protective coating may comprise a silicon based material deposited over the mandrel lines, the filler lines, and the portion of the substrate exposed by removing the anti-spacer material.

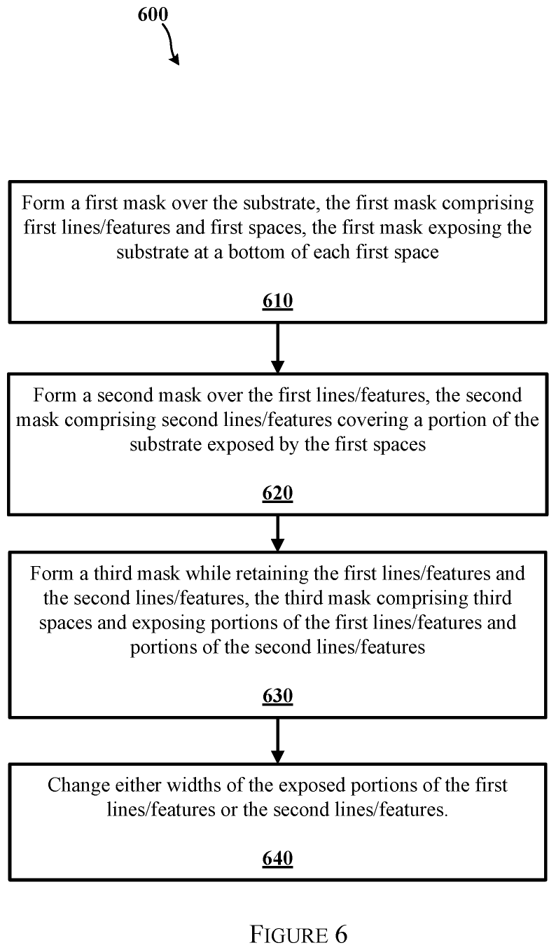

FIG. 6 illustrates a flowchart of a method 600 for patterning a substrate using three masks, in accordance with some embodiments of the invention. The processes used in method 600 for forming masks and changing widths of lines in a mask have been described above while describing FIGS. 5A-5C above.

One implementation of method 600 for patterning a substrate includes forming a first mask over the substrate (box 610), the first mask may include first lines and first spaces, the first mask exposing the substrate at a bottom of each first space. The method also includes forming a second mask over the first lines (box 620), the second mask may include second lines covering a portion of the substrate exposed by the first spaces. The method also includes forming a third mask while retaining the first lines and the second lines (box 630), the third mask may include third spaces and exposing portions of the first lines and portions of the second lines. The method also includes changing either widths of the exposed portions of the first lines or the widths of the second lines (box 640).

This disclosure describes, in various embodiments, methods of patterning a substrate with a multi-patterning technique where multiple masks are stacked over the substrate. In particular embodiments, two patterned masks are formed superimposed masks over a substrate to form a combined mask that is the etch mask for patterning openings in the substrate. The embodiments provide an advantage of independently adjusting the width of each line of any one of the two superimposed masks. Furthermore, a method using a third mask provides another advantage of defining a window to spatially select a region where the width adjustment is applied. This may be advantageous for designs that embed various functional blocks such as memory and logic in one IC.

Although, in the embodiments described above, we have referred to the features in each of the patterned masks as lines of a pattern of lines and spaces, it is understood that the inventive aspects of the described methods are applicable to other embodiments, where any of the patterned masks has a feature patterned in any shape.

Example embodiments of the invention are described below. Other embodiments can also be understood from the entirety of the specification as well as the claims filed herein.

Example 1. A method for patterning a substrate, the method includes forming a first mask over the substrate, the first mask including first features and first spaces and exposing the substrate at a bottom of each first space; forming a second mask while retaining the first features, the second mask including second features and second spaces, the second features covering a portion of the substrate exposed by the first spaces; and either selectively depositing on or selectively removing material from the second features relative to the first features to change a width of each of the second features.

Example 2. The method of example 1, further including: after changing the widths of the second features, etching openings in the substrate using a combined mask including the first and the second masks as an etch mask.

Example 3. The method of one of examples 1 or 2, where forming the first mask includes forming the first features, the first features including a first resist different from a second mask material of the second mask.

Example 4. The method of one of examples 1 to 3, where forming the first mask includes forming the first features, the first features including a hardmask different from a second mask material of the second mask.

Example 5. The method of one of examples 1 to 4, where forming the first mask includes patterning a hardmask using a double patterning process, the double patterning process including a litho-etch-litho-etch (LELE) process, a litho-freeze-litho-etch (LFLE) process, or a self-aligned sidewall image transfer (SIT) process.

Example 6. The method of one of examples 1 to 5, where forming the first mask includes forming the first features by performing an anti spacer patterning process, each first feature being either a mandrel feature or a filler feature.

Example 7. The method of one of examples 1 to 6, where performing the anti spacer patterning process includes: forming the mandrel features over the substrate using photolithography, the mandrel features including a mandrel material; overfilling spaces between the mandrel features with an overcoat material, where either the mandrel material or the overcoat material includes a chemically active species; performing a bake, the bake diffusing the chemically active species in a region within a controlled distance across a periphery between the mandrel features and the overcoat material, the chemically active species chemically converting the region across the periphery to an anti-spacer material formed self-aligned along the periphery; performing a recess etch, the recess etch controllably recessing the overcoat material to expose a top surface of the anti-spacer material, the recessing forming the filler features including the overcoat material between adjacent mandrel features; and using a solvent, selectively removing the anti-spacer material relative to the mandrel material and the overcoat material, the selective removal exposing the substrate at a bottom of anti-spacer trenches formed self-aligned along each side of the mandrel features, the anti-spacer trenches spacing the filler features from the mandrel features.

Example 8. The method of one of examples 1 to 7, further including: after forming the first mask and prior to forming a coating of a second mask material, performing a freezing process to protect the first mask from being damaged by the patterning the coating of the second mask material, the freezing process including: treating the first features with a flux of electrons; or depositing a freezing agent on the first features, the freezing agent including silicon or a resin including a cross-linker.

Example 9. The method of one of examples 1 to 8, where forming the second mask while retaining the first features includes coating a second mask material without an intervening freeze process.

Example 10. The method of one of examples 1 to 9, where the first mask is coated from propylene glycol methyl ether acetate (PGMEA) and the second mask is coated from methyl isobutyl carbinol (MIBC).

Example 11. The method of one of examples 1 to 10, where the second mask material includes a resist, the resist being an organic chemically amplified resist (CAR), hydrogen silsesquioxane (HSQ), or a metal based resist (MBR).

Example 12. The method of one of examples 1 to 11, where the MBR is a metal-oxide resist (MOR), the MOR including Sn-oxo cluster, Zr, Hf, Ti, Zn, or In.

Example 13. The method of one of examples 1 to 12, where changing the width includes increasing the width by performing an area selective deposition process configured to selectively deposit material on the second features relative to the first features and the substrate.

Example 14. The method of one of examples 1 to 13, where changing the width includes reducing the width by performing a selective etch process configured to selectively remove material from the second features relative to the first features and the substrate.

Example 15. The method of one of examples 1 to 14, where the first features include parallel features oriented in a first direction, and where the second features include parallel features oriented in a second direction, the second direction being either parallel to the first direction or perpendicular to the first direction.

Example 16. A method for patterning a substrate, the method includes forming a first mask over the substrate, the first mask including first features and first spaces, the first mask exposing the substrate at a bottom of each first space; forming a second mask while retaining the first features, the second mask including second features and second spaces, the second features covering a portion of the substrate exposed by the first spaces; and either selectively depositing on or selectively removing material from the first features relative to the second features to change a width of a portion of each of the first features exposed after forming the second mask.

Example 17. The method of example 16, where the first features include a first mask material and the second features include a second mask material, the first mask material being different from the second mask material.

Example 18. The method of one of examples 16 or 17, where changing the width includes increasing the width by performing an area selective deposition process configured to selectively deposit material on the portion of the first features exposed after forming the second mask relative to the second features and the substrate.

Example 19. The method of one of examples 16 to 18, where changing the width includes reducing the width by performing a selective etch process configured to selectively remove material from the portion of the first features exposed after forming the second mask relative to the second features and the substrate.

Example 20. The method of one of examples 16 to 19, where the selective etch process is a wet chemical etch, an isotropic plasma etch, or a thermal chemical etch process including forming an overcoat including a thermal acid generator (TAG).

Example 21. The method of one of examples 16 to 20, further including: after changing the width of the portion of the first features exposed after forming the second mask, etching openings in the substrate using a combined mask as an etch mask, the combined mask including through openings, where each through opening is a region common to the first spaces and the second spaces.

Example 22. A method for patterning a substrate, the method includes forming a first mask over the substrate, the first mask including first features and first spaces, the first mask exposing the substrate at a bottom of each first space; forming a second mask over the first features, the second mask including second features covering a portion of the substrate exposed by the first spaces; forming a third mask while retaining the first features and the second features, the third mask including third spaces and exposing portions of the first features and portions of the second features; and selectively changing either widths of the exposed portions of the first features or the second features relative to the third mask.

Example 23. The method of example 22, where the first lines include a first mask material, the second lines include a second mask material, the third lines include a third mask material, where at least one of the mask materials is different from the others.

Example 24. The method of one of examples 22 or 23, where selectively changing either widths of the exposed portions of the first features or the second features relative to the third mask includes increasing the width by performing an area selective deposition process.

Example 25. The method of one of examples 22 to 24, where selectively changing either widths of the exposed portions of the first features or the second features relative to the third mask includes reducing the width by performing an area selective etch process.

Example 26. The method of one of examples 22 to 25, further including: after changing either widths of the exposed portions of the first features or the second features, selectively removing the third mask while retaining the first mask and the second mask; and etching openings in the substrate using a combined mask comprising the first and the second masks as an etch mask.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for patterning a substrate, the method comprising:
forming a first mask over the substrate, the first mask comprising first features and first spaces and exposing the substrate at a bottom of each first space;
forming a second mask while retaining the first features, the second mask comprising second features and second spaces, the second features covering a portion of the substrate exposed by the first spaces; and
either selectively depositing on or selectively removing material from the second features relative to the first features to change a width of each of the second features.

2. The method of claim 1, further comprising:
after changing the widths of the second features, etching openings in the substrate using a combined mask comprising the first and the second masks as an etch mask.

3. The method of claim 1, wherein forming the first mask comprises forming the first features, the first features comprising a first resist different from a second mask material of the second mask.

4. The method of claim 1, wherein forming the first mask comprises forming the first features, the first features comprising a hardmask different from a second mask material of the second mask.

5. The method of claim 1, wherein forming the first mask comprises forming the first features by performing an anti-spacer patterning process, each first feature being either a mandrel feature or a filler feature.

6. The method of claim 1, further comprising:
after forming the first mask and prior to forming a coating of a second mask material, performing a freezing process to protect the first mask from being damaged by the patterning the coating of the second mask material, the freezing process comprising:
treating the first features with a flux of electrons; or
depositing a freezing agent on the first features, the freezing agent comprising silicon or a resin comprising a cross-linker.

7. The method of claim 1, wherein forming the second mask while retaining the first features comprises coating a second mask material without an intervening freeze process.

8. The method of claim 7, wherein the first mask is coated from propylene glycol methyl ether acetate (PGMEA) and the second mask is coated from methyl isobutyl carbinol (MIBC).

9. The method of claim 1, wherein changing the width comprises increasing the width by performing an area selective deposition process configured to selectively deposit material on the second features relative to the first features and the substrate.

10. The method of claim 1, wherein changing the width comprises reducing the width by performing a selective etch process configured to selectively remove material from the second features relative to the first features and the substrate.

11. A method for patterning a substrate, the method comprising:
forming a first mask over the substrate, the first mask comprising first features and first spaces, the first mask exposing the substrate at a bottom of each first space;
forming a second mask while retaining the first features, the second mask comprising second features and second spaces, the second features covering a portion of the substrate exposed by the first spaces; and
either selectively depositing on or selectively removing material from the first features relative to the second features to change a width of a portion of each of the first features exposed after forming the second mask.

12. The method of claim 11, wherein the first features comprise a first mask material and the second features comprise a second mask material, the first mask material being different from the second mask material.

13. The method of claim 11, wherein changing the width comprises increasing the width by performing an area selective deposition process configured to selectively deposit material on the portion of the first features exposed after forming the second mask relative to the second features and the substrate.

14. The method of claim 11, wherein changing the width comprises reducing the width by performing a selective etch process configured to selectively remove material from the portion of the first features exposed after forming the second mask relative to the second features and the substrate.

15. The method of claim 11, further comprising:
after changing the width of the portion of the first features exposed after forming the second mask, etching openings in the substrate using a combined mask as an etch mask, the combined mask comprising through openings, wherein each through opening is a region common to the first spaces and the second spaces.

16. A method for patterning a substrate, the method comprising:
forming a first mask over the substrate, the first mask comprising first features and first spaces, the first mask exposing the substrate at a bottom of each first space;
forming a second mask over the first features, the second mask comprising second features covering a portion of the substrate exposed by the first spaces;
forming a third mask while retaining the first features and the second features, the third mask comprising third spaces and exposing portions of the first features and portions of the second features; and
selectively changing either widths of the exposed portions of the first features or the second features relative to the third mask.

17. The method of claim 16, wherein the first features comprise a first mask material, the second lines comprise a second mask material, the third features comprise a third mask material, wherein at least one of the mask materials is different from the others.

18. The method of claim 16, wherein selectively changing either widths of the exposed portions of the first features or the second features relative to the third mask comprises increasing the width by performing an area selective deposition process.

19. The method of claim 16, wherein selectively changing either widths of the exposed portions of the first features or the second features relative to the third mask comprises reducing the width by performing an area selective etch process.

20. The method of claim 16, further comprising:
after changing either widths of the exposed portions of the first features or the second features, selectively removing the third mask while retaining the first mask and the second mask; and
etching openings in the substrate using a combined mask comprising the first and the second masks as an etch mask.
